(19) United States
(12) Patent Application Publication
(10) Pub. No.: US 2012/0280325 A1
(43) Pub. Date: Nov. 8, 2012

(54) SEMICONDUCTOR DEVICE AND METHOD OF MANUFACTURING THE SAME

(75) Inventors: Chang Seob KIM, Yongin-si (KR); Tae Kyung KIM, Cheongju-si (KR)

(73) Assignee: SK HYNIX INC., Ichon-si (KR)

(21) Appl. No.: 13/457,985

(22) Filed: Apr. 27, 2012

(30) Foreign Application Priority Data
May 3, 2011 (KR) 10-2011-0041851
Oct. 25, 2011 (KR) 10-2011-0109497

(51) Int. Cl. H01L 27/088; H01L 21/336

(52) U.S. Cl. 257/368; 438/197; 257/E27.06; 257/E21.409

(57) ABSTRACT

A semiconductor device includes first gate lines arranged at a first interval over a substrate and each configured to have a silicide layer as a highest layer, second gate lines arranged at a second interval greater than the first interval over the substrate and each configured to have the silicide layer as the highest layer, a first insulating layer formed between the first gate lines over the substrate and includes a gap; a second insulating layer formed on the sidewalls of the second gate lines, an etch-stop layer adjacent the second insulating layer, a third insulating layer located over and between the first gate lines and over and between the second gate lines, a capping layer over the third insulating layer, and a contact plug adjacent to the capping layer and the third insulating layer and coupled to a junction, the junction adjacent the substrate between the second gate lines.

### CROSS-REFERENCE TO RELATED APPLICATIONS

The present application claims priority under 35 U.S.C. §119(a) to Korean patent application numbers 10-2011-0041851 and 10-2011-0109497 filed on May 3, 2011 and Oct. 25, 2011, respectively, in the Korean Intellectual Property Office, which are incorporated herein by reference in their entirety.

### BACKGROUND

1. Technical Field

An embodiment of this disclosure relates generally to a semiconductor device and a method of manufacturing the same. Additionally, this disclosure relates generally to a semiconductor device of which includes gate lines and a method of manufacturing the same.

2. Related Art

A semiconductor device includes numerous transistors. In particular, in the semiconductor device, numerous cell transistors are arranged with a dense and repetitive structure. Additionally, the transistors have different gate structures depending on the desired type of memory. For example, in relation to a DRAM memory, the gate of the cell transistor has a stack structure of a gate oxide layer and a conductive layer for gates. In relation to a flash memory, the gate of the cell transistor may have a stack structure of a tunnel oxide layer, a floating gate, a dielectric layer, and a control gate. Also, the gates of the transistors are coupled vertically or horizontally according to the arrangement of memory cells, so that gate lines (or word lines) are coupled vertically or horizontally.

An insulating layer is filled between the gate lines, and a parasitic capacitor is formed of adjacent gate lines and an insulating layer formed between the gate lines. When voltage is supplied to the gate line, the voltage of the gate line is shifted by interference resulting from a capacitance coupling phenomenon with the parasitic capacitor. This interference phenomenon becomes severe as the intervals between the gate lines are gradually reduced in an attempt to improve or increase the degree of integration pertaining to gate lines.

Furthermore, as the width of the gate line is reduced, in order to increase the degree of integration, resistance of the gate line increases. Thus, several methods for lowering resistance of the gate line have been proposed. However, these proposed methods are disadvantageous because they increase the difficulties associated with the manufacturing process and make it difficult to obtain reappearance.

### BRIEF SUMMARY

An embodiment relates to a semiconductor device and a method of manufacturing the same.

Furthermore, the semiconductor device and method of manufacturing the device is capable of reducing an interference phenomenon and the resistance of a gate line(s).

In an embodiment of the present invention, a semiconductor device includes: first gate lines arranged at a first interval over a semiconductor substrate and each first gate line configured to have a metal silicide layer as a highest layer; second gate lines arranged at a second interval greater than the first interval over the semiconductor substrate and each second gate line configured to have the metal silicide layer as a highest layer; a first insulating layer formed between the first gate lines over the semiconductor substrate and configured to include a gap; a second insulating layer formed on sidewalls of the second gate lines which face each other; an etch-stop layer adjacent the second insulating layer; a third insulating layer located over and between the first gate lines and over and between the second gate lines; a capping layer over the third insulating layer; and a contact plug adjacent to the capping layer and the third insulating layer and coupled to a junction, the junction adjacent the semiconductor substrate between the second gate lines.

In an embodiment of the present invention, a method of manufacturing a semiconductor device includes: forming gate lines, each gate line having a silicon layer as a highest layer, the gate lines positioned over a semiconductor substrate; forming a reaction-stop layer between the gate lines so that the silicon layer is exposed; forming the exposed part of the silicon layer into a metal silicide layer; removing the reaction-stop layer; forming an insulating layer between the gate lines; and forming an insulating layer adjacent and between the metal silicide layer of the gate lines.

### BRIEF DESCRIPTION OF THE DRAWINGS

FIGS. 1A to 1G are cross-sectional views illustrating a method of manufacturing a semiconductor device according to an embodiment of the present invention; and

FIGS. 2A to 2H are cross-sectional views illustrating a method of manufacturing a semiconductor device according to another embodiment of this disclosure.

### DESCRIPTION OF EMBODIMENTS

Hereinafter, various embodiments of the present disclosure will be described in detail with reference to the accompanying drawings. The figures are provided to allow those having ordinary skill in the art to understand the scope of the embodiments of the disclosure. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

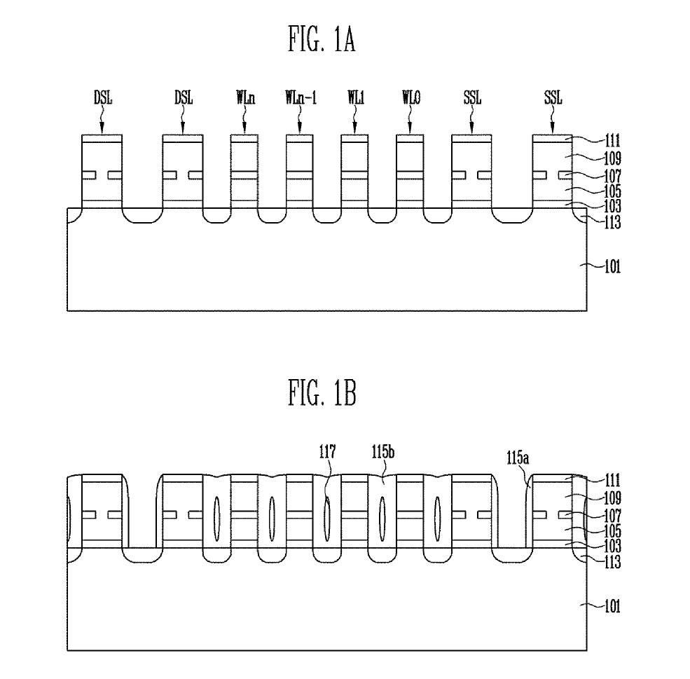

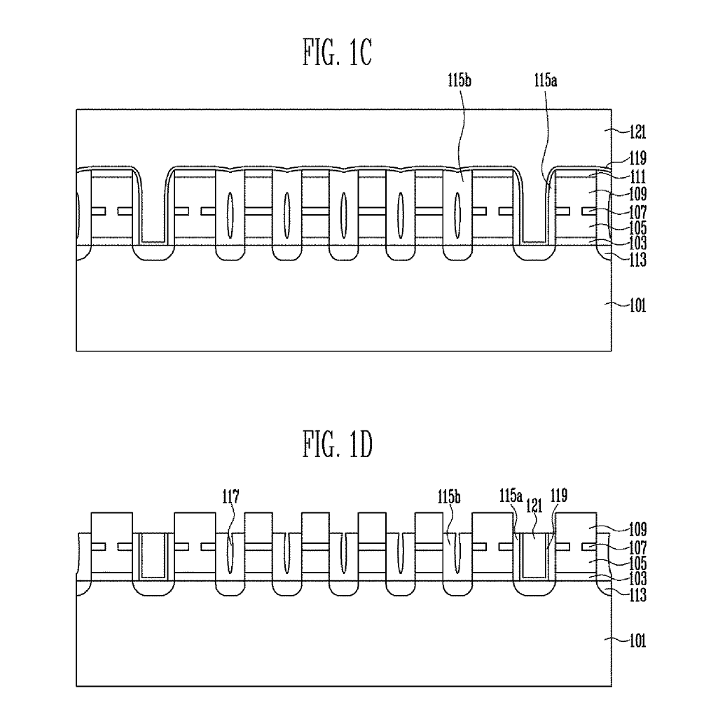

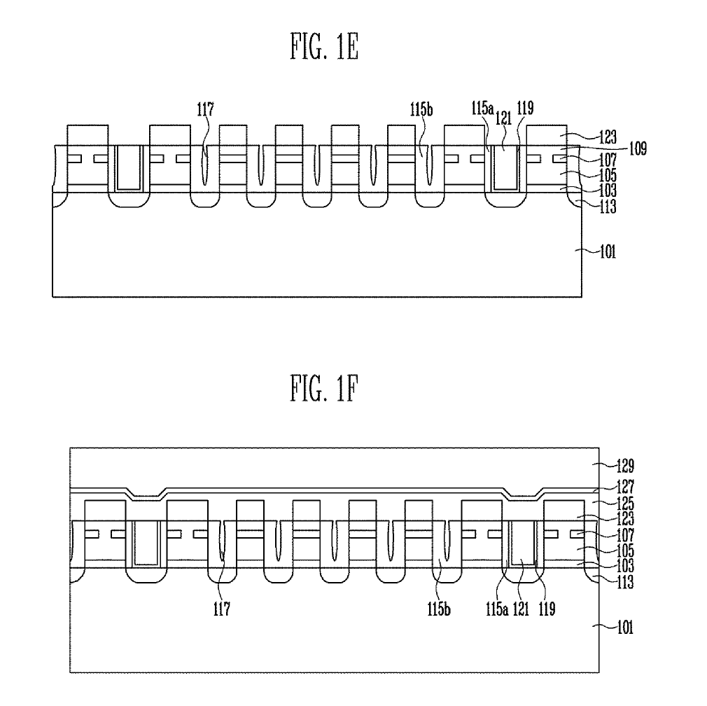

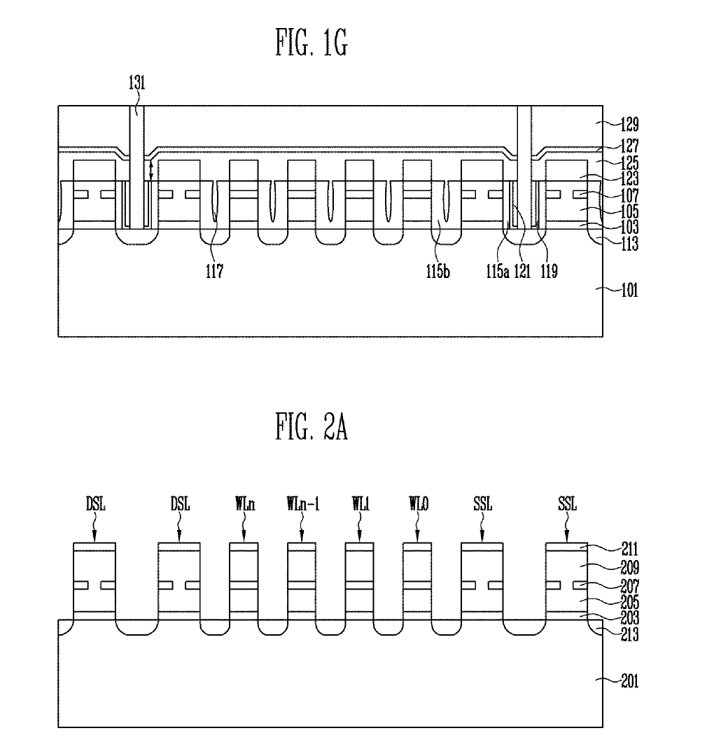

FIGS. 1A through 1G are cross-sectional views illustrating a method of manufacturing a semiconductor device according to an embodiment of this disclosure.

Referring to FIG. 1A, gate lines including source select line (SSL), word line 0 (WL0) through word line n (WLn) (which includes word line n−1 (WLn−1) and word line 1 (WL1)), and drain select line (DSL) have a second silicon layer 109 as the highest layer formed over the semiconductor substrate 101, excluding the hard mask layer 111. This is described in more detail below.

For example, in the case of NAND flash memory, gate lines including the drain select lines DSL, the word lines WL0 through WLn, and the source select lines SSL are formed. These gate lines may be formed in a cell region, and gate lines (not shown) for a high voltage transistor and a low voltage transistor may be formed in a peripheral region. The following text describes an example of a processes that may be performed in order to form the above described gate lines.

First, a well (not shown) is formed substantially within the semiconductor substrate 101, and a tunnel dielectric layer 103 is substantially formed on the surface of the semiconductor substrate 101. A gate insulating layer for the high voltage transistor or the low voltage transistor may be formed in the peripheral region. A first silicon layer 105 may be substantially formed on the tunnel dielectric layer 103. The first silicon layer 105 may be formed of, for example and not limited to, an amorphous silicon layer, a polysilicon layer, or a stack structure of them. Furthermore, 3-valence impurities or 5-valence impurities, etc., may be added to the first silicon layer 105.

The first silicon layer 105 may be etched by an etch process using an isolation mask for defining isolation regions as an etch mask. Thus, the first silicon layer 105 is patterned into a plurality of substantially parallel silicon lines. Next, trenches (not shown) having substantial parallel line forms are formed in the isolation regions by etching the tunnel dielectric layer 103 and the semiconductor substrate 101. The trenches may be substantially filled with an insulating layer. The insulating layer may be etched so that the insulating layer substantially remains on the trenches. Accordingly, isolation layers (not shown) may be formed.

A dielectric layer 107 may be formed substantially on the entire surface. The dielectric layer 107 may have a stack structure of, for example, an oxide layer, a nitride layer, and an oxide layer. In additional embodiments, the oxide layer or the nitride layer may be replaced with an insulating layer having a higher dielectric constant than the oxide layer or the nitride layer. A part of the dielectric layer 107 corresponding to regions where the select lines DSL and SSL will be formed may be etched. Accordingly, a part of the first silicon layer 105 corresponding to the regions where the select lines DSL and SSL will be formed may be substantially exposed.

A second silicon layer 109 and a hard mask layer 111 may be formed substantially over the dielectric layer 107. It may be preferred that the second silicon layer 109 be formed of, for example, a doped polysilicon layer. The hard mask layer 111, the second silicon layer 109, and the dielectric layer 107 are patterned in a direction to substantially cross a direction where the first silicon layer 105 is patterned. Accordingly, a plurality of substantially parallel control gates may be formed. Next, the first silicon layer 105 is etched.

Accordingly, the plurality of gate lines SSL, WL0 through WLn, and DSL may be formed substantially over the semiconductor substrate 101. The hard mask layer 111 may not be apart of some of the gate lines because it may be removed in a subsequent process. Accordingly, the second silicon layers 109 associated with gate lines SSL, WL0 through WLn, and DSL gate lines may become the highest layers of their respective gate lines.

Additionally, since the second silicon layer 109 may be formed in a state in which a part of the dielectric layer 107 has been etched, the first silicon layer 105 and the second silicon layer 109 of the select lines DSL and SSL may be substantially coupled through the etched part of the dielectric layer 107.

Junctions 113 may be formed substantially within the semiconductor substrate 101 substantially between the gate lines SSL, WL0 through WLn, and DSL through, for example, an ion implantation process. The junctions 113 may be formed by implanting, for exemplarily purposes only and not limited to, 5-valance impurities.

Each of the select lines DSL and SSL may have a greater width than each of the word lines WL0 through WLn. Additionally the interval between the drain select lines DSL or the source select lines SSL may be greater than the intervals between the word lines WL0 through WLn. The word lines WL0 to WLn may be defined as a first gate line group having a first interval and the select lines DSL and SSL may be defined as a second gate line group having a second interval greater than the first interval depending on the interval. The second gate line group, including a pair of the drain select lines DSL or a pair of the source select lines SSL, may be disposed between a pair of the first gate line groups.

For spacing purposes, referring to FIG. 1B, an insulating layer 115b may be formed on substantially the entire surface including the gate lines SSL, WL0 through WLn, and DSL. Additionally, insulating layer spacers 115a may be substantially formed on the sidewalls of the drain select lines DSL, substantially facing each other, by performing a first etch-back process. The first etch-back process may also create insulating layer 115b on substantially the sidewalls of the source select lines SSL. These insulating layers 115b may substantially face each other. Furthermore, the insulating layer 115b may reside between the select line SSL or DSL and the word lines WL0 or WLn, respectively, as well as between the word lines WL0 to WLn because an interval between the select line SSL or DSL and the word line WL0 or WLn and an interval between the word lines WL0 to WLn may be narrow. Accordingly, the insulating layer 115b is substantially fills between the select line SSL or DSL and the word line WL0 or WLn, respectively, and between the word lines WL0 to WLn.

Subsequently, in the process of forming the insulating layer, the interval between the select line SSL or DSL and the word line WL0 or WLn, respectively, and the interval between the word lines WL0 through WLn are narrowed. This narrowing is caused by the overhangs that may be formed as a result of the insulating layer that is formed at the top corners of the gate lines DSL, SSL, WL0 through WLn. Additionally, the insulating layer 115b may not fully fill between the select line SSL or DSL and the word line WL0 or WLn, respectively, and between the word lines WL0 to WLn. Instead air gaps 117 may be substantially formed there between. In this embodiment, the potential interference between the word lines WL0 through WLn may be minimized because parasitic capacitance between the word lines WL0 through WLn may be lowered if the air gaps 117 are formed as described above.

When the insulating layer spacers 115a and the insulating layers 115b are formed, a part of each of the junctions 113 between the drain select lines DSL and between the source select lines SSL may be exposed. However, the junctions 113 between the select line SSL or DSL and the word line WL0 or WLn, respectively, and between the word lines WL0 through WLn may be substantially covered with the insulating layer 115b.

Referring to FIG. 1C, a first etch-stop layer 119 and a first interlayer dielectric layer 121 may be sequentially formed over substantially the entire surface including the insulating layer spacers 115a and the insulating layers 115b. The first etch-stop layer 119 may be formed of, for example and not limited to, a nitride layer. The first etch-stop layer 119 may be formed on substantially the entire surface to a thickness substantially enough to maintain steps resulting from the gate lines DSL, SSL, WL0 through WLn.

Referring to FIG. 1D, the first interlayer dielectric layer 121 and the first etch-stop layer 119 are etched so that they remain only substantially between the gate lines SSL, WL0 through WLn, and DSL. Additionally, the hard mask layer 111 may be removed. Accordingly, all the top surfaces and a part of the sidewalls of the silicon layers 109 (that is, the highest layers of the gate lines SSL, WL0 to WLn, and DSL) may be substantially exposed. In particular, it may be preferred that the insulating layer spacers 115a, the insulating layers 115b, the first interlayer dielectric layer 121, the first etch-stop layer 119 be etched so that the sidewalls of the silicon layer 109 for control gates, corresponding to the highest silicon layers of the gate lines SSL, WL0 through WLn, and DSL, are exposed while maintaining that the dielectric layer 107 is substantially not exposed.

The height of a surface of the first interlayer dielectric layer 121 may be different in regions where the gate lines SSL, WL0 through WLn, and DSL are formed and regions where the gate lines SSL, WL0 through WLn, and DSL are not formed. For this reason, the height of the first insulating layer 121 remaining between the gate lines SSL, WL0 through WLn, and DSL after etching the first interlayer dielectric layer 121 may differ. Thus, it may be preferred that the first interlayer dielectric layer 121 and the first etch-stop layer 119 be etched by using, for example but not limited to, a chemical mechanical polishing (CMP) process and a second etch-back process at substantially the same time. Thus, the chemical mechanical polishing (CMP) process may be performed until the hard mask layers 111 of the gate lines SSL, WL0 to WLn, and DSL are substantially exposed, the height of the first interlayer dielectric layer 121 remaining between the gate lines SSL, WL0 through WLn, and DSL may become substantially uniform. Additionally, when the insulating layer spacers 115a, the insulating layers 115b, the first interlayer dielectric layer 121, and the first etch-stop layer 119 are etched by the second etch-back process, the sidewalls of the highest silicon layers 109 of the gate lines SSL, WL0 to WLn, and DSL may substantially be uniformly exposed.

Accordingly, the insulating layer spacers 115a, the insulating layers 115b, the first interlayer dielectric layers 121, and the first etch-stop layers 119 remain higher than the gate lines SSL, WL0 through WLn, and DSL between the gate lines SSL, WL0 through WLn, and DSL.

After the insulating layer 115b between the word lines WL0 through WLn is etched by the second etch-back process, the air gaps 117 formed within the respective insulating layer 115b may be exposed.

Referring to FIG. 1E and FIG. 1D, the exposed parts of the silicon layers 109 for control gates are formed into metal silicide layers 123 by performing a silicidation process. More specifically, a metal layer may be formed by depositing metal material (for example, and not limited to, tungsten, cobalt, or nickel, etc.) on substantially the entire surface so that the exposed parts of the silicon layers 109 may be substantially surrounded. The metal silicide layers 123 may be formed by reacting the silicon of the silicon layers 109, coming in substantial contact with the metal layer, with the metal of the metal layer using, for example but not limited to, a thermal treatment process. If the metal layer is substantially made of tungsten, tungsten silicide layers may be formed. If the metal layer is made substantially of cobalt, cobalt silicide layers may be formed. If the metal layer is substantially made of nickel, nickel silicide layers may be formed. Additionally, the metal layer remaining without reacting with the silicon layers 109 may be removed.

The metal silicide layers 123 are formed in a state when the tops of the silicon layers 109 are substantially exposed by the insulating layer spacers 115a, the insulating layers 115b, the first etch-stop layers 119, and the first interlayer dielectric layers 121. Accordingly, the metal silicide layers 123 may be automatically aligned substantially over the gate lines SSL, WL0 through WLn, and DSL.

FIG. 1F illustrates a second interlayer dielectric layer 125, a capping layer 127, and a third interlayer dielectric layer 129. These layers may be sequentially formed over the entire surface including the metal silicide layers 123. Here, the air gaps 117 substantially remain intact because the exposed inlets of the air gaps 117 may be substantially clogged by overhangs formed by the second interlayer dielectric layer 125 when forming the second interlayer dielectric layer 125.

The capping layer 127 functions to substantially prevent mobile ions, such as, for example, hydrogen ions generated in a subsequent process, from infiltrating the gate lines SSL, WL0 through WLn, and DSL. Furthermore, the capping layer 127 may function as a second etch-stop layer. The capping layer 127 may be made of different material from the layers 121, 125, and 129. For example, the capping layer 127 may be formed of a nitride layer.

In the state where the metal silicide layers have been exposed, the second interlayer dielectric layer 125 may be formed on substantially the entire surface including the metal silicide layers 123. Thus, the second interlayer dielectric layer 125 may substantially come in direct contact with the metal silicide layers 123. That is, a hard mask or another layer may not exist between the metal silicide layers 123 and the second interlayer dielectric layer 125.

Furthermore, in the state where the metal silicide layers 123 have been substantially exposed, the capping layer 127 may be formed after forming the second interlayer dielectric layer 125. Thus, the capping layer 127 may substantially prevent mobile ions, such as, for example, hydrogen ions generated in a subsequent process, from infiltrating the gate lines SSL, WL0 through WLn, and DSL.

Referring to FIG. 1G, contact holes may be formed, for example, by sequentially etching the third interlayer dielectric layer 129, the second etch-stop layer 127, the second interlayer dielectric layer 125, the first interlayer dielectric layers 121, and the first etch-stop layers 119 so that the junctions 113 between the source select lines SSL and between the drain select lines DSL may be substantially exposed. Contact plugs 131 may be formed by filling the contact holes with a conductive material.

From a structural viewpoint of the semiconductor device formed according to this embodiment, the highest layers of the first gate lines WL0 through WLn included in the first gate line group are the metal silicide layers 123 and are arranged at the first interval over the semiconductor substrate 101. The highest layers of the second gate lines DSL or SSL included in the second gate line group are the metal silicide layers 123 and are arranged at the second interval greater than the first interval over the semiconductor substrate 101.

The insulating layers 115b may be used for spacers, each including an air gap 117, and may be formed over the semiconductor substrate 101 between the gate lines WL0 through WLn. The insulating layer spacers 115a may be substantially formed on the sidewalls of the gate lines DSL or SSL which substantially face each other. Additionally, the etch-stop layer 119 may be formed on the sidewalls of each of the insulating layer spacers 115a.

The third insulating layer 125 may be substantially formed on the entire surface so that the space between the gate lines WL0 through WLn, the space between the drain select lines DSL, and the space between the source select lines SSL are substantially filled. The capping layer 127 may be formed over or substantially on the third insulating layer 125. The capping layer 127 may be formed of, for example and not limited to, a nitride layer and may be formed substantially over the gate lines SSL, WL0 through WLn, and DSL.

The contact plugs 131 may be formed through the capping layer 127 and the third insulating layer 125 and may be substantially coupled to the junctions 113 formed in the semiconductor substrate 101 between the gate lines DSL and SSL. The first interlayer dielectric layer 121 may be further formed between the etch-stop layer 119 and the contact plug 131.

The highest layers of the gate lines SSL, WL0 through WLn, and DSL may be formed of a metal silicide layer 123 without the existence of a hard mask on the metal silicide layers 123. Thus, the metal silicide layers 123 may be adjacent or may directly come in substantial contact with the second insulating layers 125.

As described above, in accordance with the method and structure according to the embodiment, although the width of each of the gate lines SSL, WL0 through WLn, and DSL may be narrowed, resistance of the gate lines SSL, WL0 through WLn, and DSL may be reduced because the metal silicide layers 123 having low resistance are formed. Furthermore, when forming the second interlayer dielectric layers 125, the air gap 117 may remain between the word lines WL0 through WLn. Accordingly, parasitic capacitance between the word lines WL0 through WLn may be reduced, and thus interference between the word lines WL0 through WLn may be minimized.

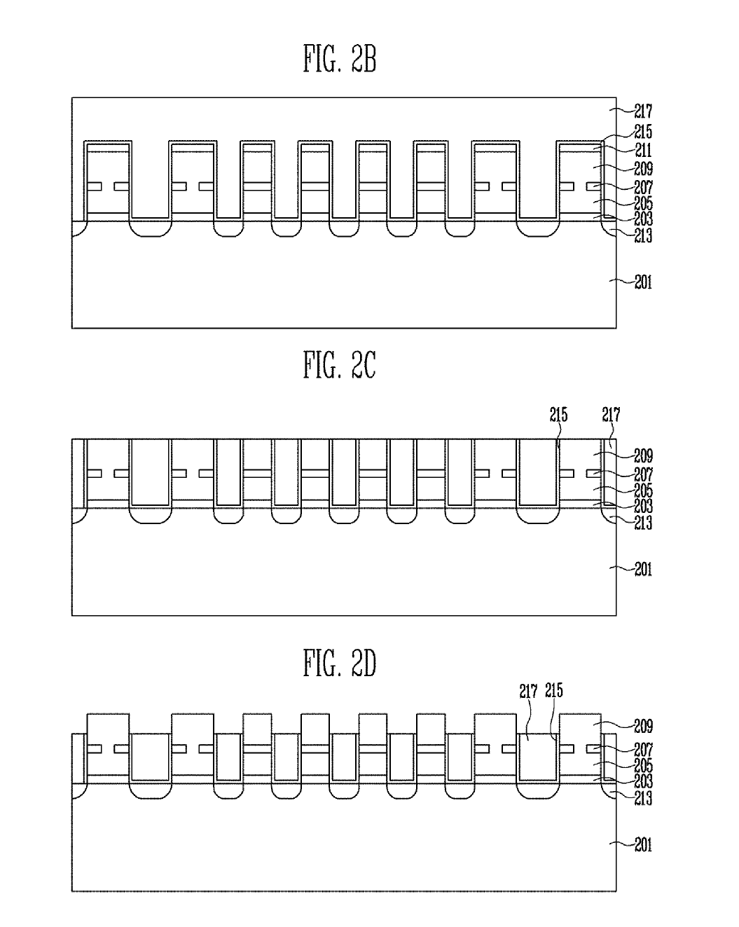

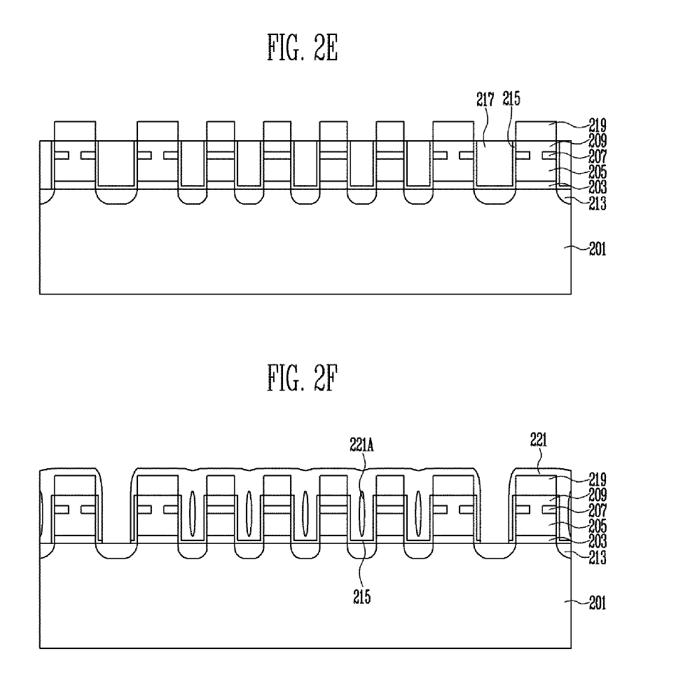

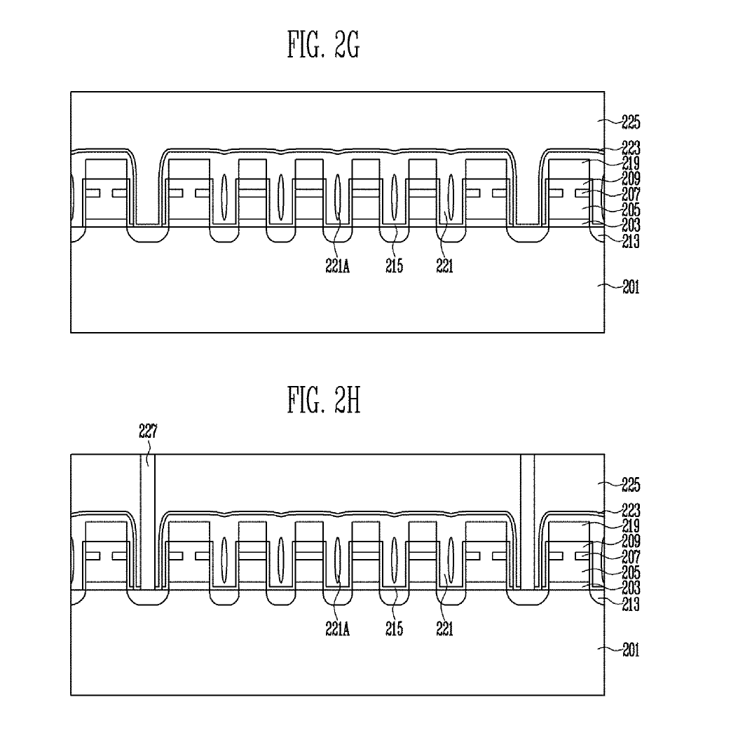

FIGS. 2A through 2H are a variation of the above embodiments associated with FIGS. 1A through 1G, and also illustrate a method of minimizing interference and reducing resistance of gate lines.

FIGS. 2A through 2H are cross-sectional views illustrating a method of manufacturing a semiconductor device.

Referring to FIG. 2A, gate lines SSL, WL0 through WLn, and DSL are illustrated having silicon layers 209 as the highest layers formed over semiconductor substrate 201. Junctions 213 are formed substantially within the semiconductor substrate 201 between the gate lines SSL, WL0 through WLn, and DSL.

For example, in the case of NAND flash memory, the gate lines SSL, WL0 through WLn, and DSL may include the source select lines SSL, the word lines WL0 through WLn, and the drain select lines DSL. Each of the gate lines SSL, WL0 through WLn, and DSL may have a stack structure, including a tunnel dielectric layer 203, a silicon layer 205 for, for example, floating gates, a dielectric layer 207, and the silicon layer 209 for, for example, control gates. Hard mask layers 211 may be substantially formed over the respective gate lines SSL, WL0 through WLn, and DSL. The hard mask layer 211 may be formed of, for example, an oxide layer. The gate lines SSL, WL0 through WLn, and DSL and the junctions 213 may be formed using the same method as that described with reference to FIG. 1A.

Next, a reaction-stop layer for allowing a metal layer to react with the silicon layers 209 for control gates corresponding to the highest silicon layers of the gate lines SSL, WL0 through WLn, and DSL, but preventing the metal layer from reacting with the remaining silicon structures (for example, the silicon layer for floating gates and the semiconductor substrate) in a silicidation process is formed between the gate lines SSL, WL0 through WLn, and DSL. This is described in detail below.

Referring to FIG. 2B, a passivation layer 215 is formed on the entire surface including the gate lines SSL, WL0 through WLn, and DSL. The passivation layer 215 may be formed by depositing an oxide layer. For example, by using a chemical vapor deposition (CVD) method. A reaction-stop insulating layer 217 is formed on the entire surface including the passivation layer 215 so that a space between the gate lines SSL, WL0 through WLn, and DSL is substantially filled. The reaction-stop insulating layer 217 may be formed of an insulating layer, for example but not limited to, a spin-on carbon (SOC) layer, or photoresist having fluidity. Since the reaction-stop insulating layer 217 is made of material having fluidity, the reaction-stop insulating layer 217 may be filled between the gate lines SSL, WL0 through WLn, and DSL, leaving substantially no air gaps or no air gaps between the gate lines.

The passivation layer 215 and the reaction-stop insulating layer 217 form a reaction-stop layer. The passivation layer 215 may function to prevent impurities, included in the reaction-stop insulating layer 217, from substantially infiltrating the gate lines SSL, WL0 through WLn, and DSL. However, the passivation layer 215 may be omitted depending on material forming the reaction-stop insulating layer 217.

Referring to FIG. 2C, the hard mask layers 211 over the gate lines SSL, WL0 through WLn, and DSL are substantially removed, and for example, a chemical mechanical polishing (CMP) process may be performed until the silicon layers 209 for the control gate are substantially exposed. Thus, the passivation layer 215 and the reaction-stop insulating layer 217 remain between the gate lines SSL, WL0 through WLn, and DSL. After, for example, the chemical mechanical polishing (CMP) process, a top surface of the entire structure may become substantially flat, and the reaction-stop insulating layer 217 remaining between the gate lines SSL, WL0 through WLn, and DSL may substantially be of uniform height.

Referring to FIG. 2D, the sidewalls of the highest silicon layers 209 of the gate lines SSL, WL0 through WLn, and DSL are substantially exposed by etching the passivation layers 215 and the reaction-stop insulating layers 217 by, for example, using a first etch-back process. It may be preferred that the passivation layers 215 and the reaction-stop insulating layers 217 be etched such that substantially all the sidewalls of the silicon layers 209 are exposed. In this embodiment, however, the silicon layers 209 may be etched just until the sidewalls of the dielectric layer 207 are exposed. For this reason, the passivation layers 215 and the reaction-stop insulating layers 217 may be etched so that only the upper sidewalls of the silicon layers 209 are exposed. Additionally, the first etch-back process may be performed by using an etchant that may etch the passivation layers 215 and the reaction-stop insulating layers 217 at the same rate.

The reaction-stop insulating layers 217 may have a substantially uniform etch thickness because the first etch-back process may be performed in the state in which the reaction-stop insulating layers 217 maintain a substantially uniform height. Thus, the sidewalls of the highest silicon layers 209 of the gate lines SSL, WL0 through WLn, and DSL may be uniformly exposed.

Accordingly, the reaction-stop layers, each including the passivation layer 215 and the reaction-stop insulating layer 217, may have a lower height than the gate lines SSL, WL0 through WLn, and DSL between the gate lines SSL, WL0 through WLn, and DSL.

A cleaning process may be performed after the first etch-back process. In this embodiment, it can be possible to fully and substantially remove etch by-products and to substantially prevent the etch by-products from remaining within the air gaps because the cleaning process may be performed without the air gaps.

Referring to FIG. 2E, the substantially exposed parts of the silicon layers 209 for the control gates may be formed into metal silicide layers 219 by performing, for example, a silicidation process. The metal silicide layers 219 may be formed of, for example but not limited to, any one of tungsten silicide layers, cobalt silicide layers, and nickel silicide layers. Additionally, the metal silicide layers 219 may be formed using the same method as that described with reference to FIG. 1E.

The metal silicide layers 219 may be automatically aligned over the respective gate lines SSL, WL0 through WLn, and DSL because they are formed in the state in which only the tops of the silicon layers 209 are exposed between the reaction-stop layers (215 and 217).

Furthermore, the metal silicide layers 219 may be formed in the state in which an air gap is substantially not formed in the reaction-stop layers (215 and 217) between the gate lines SSL, WL0 through WLn, and DSL. Thus, a part of the metal layer does not remain within the air gaps when removing a metal layer after forming the metal silicide layers 219.

Referring to FIG. 2F, the reaction-stop insulating layers 217 may be removed or substantially removed. In some embodiments, for example in FIG. 2E, the reaction-stop insulating layers 217 of the reaction-stop layers (215 and 217) may be removed first, and the metal silicide layers 219 may then be formed, for example, by the silicidation process in the state in which only the passivation layers 215 have remained.

The passivation layers 215 substantially protect the sidewalls of the gate lines SSL, WL0 through WLn, and DSL when removing the reaction-stop insulating layers 217. Furthermore, the passivation layers 215 may remain in order to substantially prevent impurities, included in an interlayer dielectric layer formed in a subsequent process, from infiltrating the gate lines SSL, WL0 through WLn, and DSL.

Next, after forming an insulating layer 221 for spacers on substantially the entire surface, insulating layer spacers may be formed on the sidewalls of the drain select lines DSL and the source select lines SSL, facing each other, by performing, for example, a second etch-back process. Furthermore, since an interval between the select line SSL or DSL and the word line WL0 or WLn, respectively, and an interval between the word lines WL0 through WLn are narrow, the insulating layer 221 may be substantially filled between the select line SSL or DSL and the word line WL0 or WLn, respectively, and between the word lines WL0 through WLn. Accordingly, a part of the junction 213 between the drain select lines DSL and a part of the junction 213 between the source select lines SSL may be substantially exposed, but the junctions 213 formed between the word lines WL0 through WLn may be fully covered or substantially covered with the insulating layer 221.

It may be preferred, for example, that the insulating layer 221, for spacers, be formed of an undoped silicate glass (USG) layer using a plasma-enhanced chemical vapor deposition (PE-CVD) method. The USG layer may be formed, for example, by using SiH₄ as a source gas, N₂O as a reaction gas, and nitrogen as a carrier gas. The USG layer may be formed, for example, by supplying RF power of 800 W to 1200 W in a temperature range of 350° C. to 450° C. In particular, the amount of the USG layer deposited on the planes of the gate lines SSL, WL0 through WLn, and DSL and the amount of the USG layer deposited on the sidewalls of the gate lines SSL, WL0 through WLn, and DSL may differ depending on the flow rate of SiH₄. For example, if SiH₄ having a greater amount (for example, 350 standard cubic meter per minute (sccm) to 550 sccm) than SiH₄ of 350 sccm is supplied, the USG layer may be deposited thicker in the horizontal plane than in the vertical plane, and thus the degree of overhang generated at the top corners of the gate lines SSL, WL0 through WLn, and DSL may be increased. Accordingly, if the amount of SiH₄ is increased, the insulating layer 221 may be formed so that an air gap is generated without fully filling the spaces between the word lines WL0 through WLn.

If the flow rate of the source gas for forming the insulating layer 221 is controlled as described above, the amount of the insulating layer 221 deposited on the top corners of the gate lines SSL, WL0 through WLn, and DSL can be controlled, and the overhangs formed at the top corners of the gate lines SSL, WL0 through WLn, and DSL may have different thicknesses. If, for example, the overhangs of the insulating layer 221 are increased, the insulating layers 221 may come in contact with each other at the corners of adjacent word lines before the insulating layer 221 is filled between the word lines WL0 through WLn. Consequently, the insulating layer 221 may not fully be filled between the word lines WL0 through WLn, and air gaps 221A may uniformly be formed between the word lines WL0 through WLn.

Referring to FIG. 2G, an etch-stop layer 223 may be substantially formed on the surface including the insulating layers 221. The etch-stop layer 223 may be formed of, for example, a nitride layer. An interlayer dielectric layer 225 may be formed on or adjacent the etch-stop layer 223.

Referring to FIG. 2H, contact holes may be formed, for example, by sequentially etching the interlayer dielectric layer 225 and the etch-stop layer 223 so that the junction 213 between the source select lines SSL and the junction 213 between the drain select lines DSL are substantially exposed. Contact plugs 227 may be formed by filling the contact holes with, for example, conductive material.

In accordance with the previous embodiment, although the width of each of the gate lines SSL, WL0 through WLn, and DSL may be narrowed, resistance of the gate lines SSL, WL0 through WLn, and DSL may be reduced because the metal silicide layers 123 have low resistance are formed. Furthermore, since the air gaps 117 are formed between the word lines WL0 through WLn, parasitic capacitance between the word lines WL0 through WLn may be reduced, and thus interference between the word lines WL0 through WLn may be minimized.

In accordance with another embodiment, the air gaps 221A may not be exposed after forming the air gaps 221A. Accordingly, there is little to no possibility that etch by-products may remain within the air gaps 221A and that metal material may remain even after the silicidation process.

Furthermore, damage to the air gaps 221A in a subsequent process may be prevented. Accordingly, the air gaps 221A may be uniformly formed between the word lines WL0 through WLn, and parasitic capacitance between the word lines WL0 through WLn may be uniformly controlled and reduced.

In particular, although only one etch-stop layer is used, all the gate lines SSL, WL0 through WLn, and DSL may be protected when forming the contact holes. Thus, it is possible to prevent or substantially prevent the gate lines SSL, WL0 through WLn, and DSL from being coupled to the contact plugs 227 because the gate lines SSL, WL0 through WLn, and DSL may be substantially exposed.

Furthermore, the number of process steps may be reduced by using only one etch-stop layer thereby reducing the number of interlayer dielectric layers formed.

In accordance with the embodiments of this disclosure, the silicon layers are formed into the metal silicide layers in the state in which the silicon layers 109 or 209 corresponding to the highest layers of the gate lines SSL, WL0 through WLn, and DSL are being exposed. Accordingly, the metal silicide layers 123 or 219 may be self-aligned substantially over the respective silicon layers 109 or 209, and thus an etch process for dividing the metal silicide layers 123 or 219 for every gate line may not be necessary.

As described above, in accordance with this disclosure, the process can be simplified, a shift in the voltage of adjacent gate lines due to voltage supplied to a gate line can be minimized, and resistance of the gate lines may be reduced. In addition, the gate lines may be safely protected by, for example, the nitride layer.

What is claimed is:

1. A semiconductor device, comprising:
first gate lines arranged at a first interval over a semiconductor substrate and each first gate line comprising a plurality of layers with a metal silicide layer as the top layer;
second gate lines arranged at a second interval greater than the first interval over the semiconductor substrate and each second gate line comprising a plurality of layers with a metal silicide layer as the top layer;
a first insulating layer formed between the first gate lines over the semiconductor substrate and configured to include an air gap;
a second insulating layer formed on sidewalls of the second gate lines adjacent to each other;
an etch-stop layer formed on sidewalls of the second insulating layer;
a third insulating layer formed over and between the first gate lines and over and between the second gate lines;
a capping layer formed over the third insulating layer; and
a contact plug formed through the capping layer and the third insulating layer in the second interval so as to couple to a junction formed in the semiconductor substrate between the second gate lines.

2. The semiconductor device of claim 1, wherein each of the metal silicide layers is any one of a tungsten silicide layer, a cobalt silicide layer, and a nickel silicide layer.

3. The semiconductor device of claim 1, further comprising a fourth insulating layer formed between the etch-stop layer and the contact plug.

4. The semiconductor device of claim 1, wherein the capping layer is formed of a nitride layer.

5. The semiconductor device of claim 1, wherein the first insulating layer has a lower height than the first gate lines.

6. The semiconductor device of claim 1, wherein the third insulating layer comes in contact with the metal silicide layer of the first and the second gate lines.

7. A method of manufacturing a semiconductor device, comprising:
forming gate lines, each gate line comprising a plurality of layers with a silicon layer as the top layer, over a semiconductor substrate;
forming a reaction-stop layer between the gate lines so that the silicon layer of each gate line is exposed;
forming the exposed part of the silicon layer of each gate line into a metal silicide layer;
removing the reaction-stop layer; and
forming an insulating layer over and between the gate lines, each gate line comprising the metal silicide layer.

8. The method of claim 7, wherein the reaction-stop layer between the gate lines has a lower height than the gate lines.

9. The method of claim 7, wherein:
the reaction-stop layer has a stack structure of a passivation layer and a reaction-stop insulating layer, and
the reaction-stop insulating layer and the passivation layer are removed before forming the metal silicide layer.

10. The method of claim 7, wherein forming a reaction-stop layer between the gate lines so that the silicon layer is exposed comprises:
forming a passivation layer over the gate lines and over the semiconductor substrate;
forming a reaction-stop insulating layer over the passivation layer; and
etching the passivation layer and the reaction-stop insulating layer so that the passivation layer and the reaction-stop insulating layer remain only between the gate lines.

11. The method of claim 10, wherein the passivation layer is formed of an oxide layer.

12. The method of claim 10, wherein the reaction-stop insulating layer is formed of a spin-on carbon (SOC) layer.

13. The method of claim 9, wherein the reaction-stop insulating layer is formed of a photoresist.

14. The method of claim 10, wherein etching the passivation layer and the reaction-stop insulating layer comprises:
performing a chemical mechanical polishing (CMP) process so that the passivation layer and the reaction-stop insulating layer remain only between the gate lines; and
etching the passivation layer and the reaction-stop layer so that the passivation layer and the reaction-stop layer between the gate lines have a lower height than the gate lines using an etch-back process.

15. The method of claim 7, wherein the metal silicide layer is any one of a tungsten silicide layer, a cobalt silicide layer, and a nickel silicide layer.

16. The method of claim 7,
wherein each gate line is one of a source select line, a word line, and a drain select line,
wherein a gap is formed within a portion of the insulating layer between two adjacent word lines, between a source select line and a word lines adjacent to each other, and between a drain select line and a word line adjacent to each other, and
wherein the insulating layer is formed on sidewalls of two adjacent source select lines and on sidewalls of two adjacent drain select lines.

17. The method of claim 7, further comprising:
forming an etch-stop layer on the insulating layer;
forming an interlayer dielectric layer on the etch-stop layer;
forming a contact hole by etching predetermined portions of the interlayer dielectric layer and the etch-stop layer; and
forming a contact plug in the contact hole.

18. The method of claim 7, wherein the insulating layer is formed of an undoped silicate glass (USG) layer.

19. The method of claim 18, wherein the USG layer is formed using a SiH₄ as a source gas and N₂O as a reaction gas.

20. The method of claim 19, wherein a flow rate of the SiH₄ gas is adjusted to control an amount of the insulating layer formed.

21. The method of claim 20, wherein the flow fate of the SiH₄ gas is 350 sccm to 550 sccm.
